(19) United States
(12) Patent Application Publication
(10) Pub. No.: US 2021/0301203 A1
(43) Pub. Date: Sep. 30, 2021

(54) GREEN EMITTING PHOSPHOR AND LIGHTING DEVICE

(71) Applicant: Osram OLED GmbH, Regensburg (DE)

(72) Inventors: Thorsten SCHROEDER, Munich (DE); Daniel BICHLER, Augsburg (DE); Gina Maya ACHRAINER, Greifenberg (DE); Christian KOCH, Wehringen (DE); Simon DALLMEIR, Biessenhofen (DE)

(21) Appl. No.: 17/264,301

(22) PCT Filed: Jun. 5, 2019
(86) PCT No.: PCT/EP2019/064713

§ 371 Date: Jan. 29, 2021

(30) Foreign Application Priority Data
Jul. 31, 2018 (DE) 10 2018 212 724.7

(51) Int. Cl. C09K 11/77; C09K 11/64; C01F 7/04; H01L 33/50

(52) U.S. Cl. CPC C09K 11/7734; C09K 11/641; C01F 7/04; C01P 2002/77; C01P 2002/52; C01P 2002/76; H01L 33/502

(57) ABSTRACT

The disclosure provides a potassium aluminate phosphor which is doped with Mn+ or with Eu+ and Mn+, a lighting device, and methods for making the same. This disclosure also provides a conversion light emitting diode (LED) including a semiconductor layer sequence set up to emit electromagnetic primary radiation; and a conversion element including an Mn²⁺-doped potassium aluminate phosphor or an Eu²⁺- and Mn²⁺-doped potassium aluminate phosphor and at least partly converts the electromagnetic primary radiation to electromagnetic secondary radiation, wherein the Mn²⁺-doped potassium aluminate phosphor or the Eu²⁺- and Mn²⁺-doped potassium aluminate phosphor has a general empirical formula KₓAl_{11+y}O_{17+z}:Mn²⁺, or KₓAl_{11+y}O_{17+z}:(Mn²⁺,Eu²⁺).

### REFERENCE TO RELATED APPLICATIONS

The present application is a national stage entry according to 35 U.S.C. § 371 of PCT Application No.: PCT/EP2019/064713 filed on Jun. 5, 2019, which claims priority to German Patent Application No.: 10 2018 212 724.7 filed on Jul. 31, 2018, both of which are incorporated by reference herein in their entirety.

### TECHNICAL FIELD

The disclosure relates to a phosphor and to a lighting device that includes the phosphor.

### BACKGROUND

Phosphors that can efficiently be excited with ultraviolet and/or blue primary radiation and have efficient emission in the green spectral region are of great interest for the production of white and colored conversion LEDs. Conversion LEDs are used, for example, for general lighting.

Known green-emitting phosphors frequently have very broad emission bands, resulting in occurrence of radiation losses through partial emission in the UV region.

For example, EP2275512 A2 discusses green-emitting phosphors.

It would be desirable to provide a phosphor that emits radiation in the green spectral region and to provide a lighting device including the phosphor.

### SUMMARY

The present disclosure provides a phosphor and a lighting device.

An Mn²⁺-doped potassium aluminate phosphor and an Eu²⁺- and Mn²⁺-doped potassium aluminate phosphor are provided. In other words, the potassium aluminate phosphor has been doped either with Mn²⁺ or with Eu²⁺ and Mn²⁺. For example, Mn²⁺ may be the dopant of the potassium aluminate phosphor or Eu²⁺ and Mn²⁺ may be the dopants of the potassium aluminate phosphor. The Mn²⁺- or Eu²⁺- and Mn²⁺-doped potassium aluminate phosphor may also be referred to hereinafter as phosphor.

In some aspects of this disclosure, potassium aluminate phosphors doped with Mn²⁺ or with Eu²⁺ and Mn²⁺, on excitation with primary radiation, have emission or secondary radiation in the green spectral region and additionally show a small full width at half maximum (FWHM).

The full width at half maximum is understood here and hereinafter to mean the spectral width at half the height of the maximum of an emission peak or an emission band.

By contrast, it has been found that potassium aluminate phosphors doped solely with Eu²⁺ have broadband emission in the blue spectral region. Doping of the potassium aluminate phosphor with Mn²⁺ has been found to be useful for narrowband emission in the green spectral region.

The blue spectral region may be considered to be the region of the electromagnetic spectrum between 400 nm and 490 nm inclusive.

The green spectral region may be considered to be the region of the electromagnetic spectrum between 490 nm and 550 nm inclusive.

Eu²⁺- and Mn²⁺-doped potassium aluminate phosphors additionally exhibit high absorption capacity in the near UV to blue region, and can thus be excited efficiently with primary radiation within this wavelength range.

Phosphors are described hereinafter by empirical formulae. It is possible in the case of the provided empirical formulae that the phosphor includes further elements, for instance in the form of impurities, where these impurities together may have a proportion by weight of the phosphor of not more than 1 permille or 100 ppm (parts per million) or 10 ppm.

In at least one aspect, the phosphor has the general empirical formula KₓAl_{11+y}O_{17+z}:Mn²⁺ or KₓAl_{11+y}O_{17+z}:(Mn²⁺, Eu²⁺). In KₓAl_{11+y}O_{17+z}:(Mn²⁺,Eu²⁺), KₓAl_{11+y}O_{17+z} has thus been doped with Mn²⁺ and Eu²⁺, whereas, in KₓAl_{11+y}O_{17+z}:Mn²⁺, KₓAl_{11+y}O_{17+z} has been doped solely with Mn²⁺. The following condition applies to the phosphor: x+3(11+y)=2(17+z), where 0<x, −17<z and −11<y.

In at least one aspect, the Mn²⁺- or Eu²⁺- and Mn²⁺-doped potassium aluminate phosphor, for example, KₓAl_{11+y}O_{17+z}:Mn²⁺ or KₓAl_{11+y}O_{17+z}:(Mn²⁺, Eu²⁺), crystallizes in a crystal structure isotypical to sodium β-aluminate. In other words, the phosphor crystallizes in the hexagonal P6₃/mmc space group.

What is meant, for example, by the fact that two compounds crystallized in an isotypic crystal structure is that the atoms of one compound occupy the same position within the crystal structure as the corresponding atoms of the other compound. As a result, the linkages of construction units within the structures remain unchanged.

Within the crystal structure, for example, there are spinel-like layers formed from vertex-linked AlO₄ tetrahedra and corner-linked AlO₆ octahedra. These layers are separated from one another by the arrangement of K⁺ and O²⁻ ions along the crystallographic c axis. Mn²⁺ or Mn²⁺ and Eu²⁺ here may partly replace K⁺ or Al³⁺.

If there is a change in the proportion x of potassium within the phosphor KₓAl_{11+y}O_{17+z}:Mn²⁺ or KₓAl_{11+y}O_{17+z}:(Mn²⁺, Eu²⁺), the charge is balanced via the aluminum content through y and/or the oxygen content through z.

When 0<x<1, it is possible here that the proportion of aluminum is increased and hence 0<y or the proportion of oxygen is reduced and hence z<0. If the proportion of oxygen is reduced, there are what are called defect sites within the crystal structure at positions occupied by oxygen ions in the case that x=1. The positions of the oxygen, i.e. the corners of the AlO₄ tetrahedra and/or of the AlO₆ octahedra, and the oxygen positions arranged between the layers formed from vertex-linked AlO₄ tetrahedra and corner-linked AlO₆ octahedra are thus partly unoccupied. If, by contrast, the proportion of aluminum is increased, there are additional aluminum ions at interstitial lattice sites that are unoccupied in the case that x=1. It is also possible that the charge is balanced by a reduction in the layer thickness of individual layers (and hence the negative overall charge thereof), which proceeds from vertex-linked AlO₄ tetrahedra and corner-linked AlO₆ octahedra, and hence in a reduction both in the aluminum content and in the oxygen content. The defect sites, occupation of interstitial lattice sites or the reduction in individual layer thicknesses here are so small that there is no change in what is called the average crystal structure, as defined by crystal structure analysis by x-ray diffraction.

When 1<x<2, it is possible that the proportion of aluminum is reduced and hence y<0, or that the proportion of oxygen is increased and hence 0<z. If the proportion of aluminum is reduced, what are called defect sites occur within the crystal structure at positions occupied by aluminum ions in the case that x=1. The positions of the aluminum, i.e. the centers of the AlO₄ tetrahedra and/or of the AlO₆ octahedra, are thus partly unoccupied. If, by contrast, the proportion of oxygen is increased, there are additional oxygen ions at interstitial lattice sites that are unoccupied in the case that x=1. It is also possible that the charge is balanced by an increase in the layer thickness of individual layers (and hence the negative overall charge thereof) that are formed from vertex-linked AlO₄ tetrahedra and corner-linked AlO₆ octahedra, and hence in an increase both in the aluminum content and in the oxygen content. The defect sites, occupation of interstitial lattice sites or the increase in individual layer thicknesses here are so small that there is no change in what is called the average crystal structure.

In at least one aspect, the phosphor has the general empirical formula KₓAl_{11+y}O_{17+z}:Mn²⁺ or KₓAl_{11+y}O_{17+z}:(Mn²⁺, Eu²⁺). The following condition applies to the phosphor:

x+3(11+y)=2(17+z), where 0<x<2,
−½<z<½ and −⅓<y<⅓. This small change in the proportion of aluminum and/or oxygen can ensure that there is no change in the average crystal structure, or that the defects, the occupation of interstitial lattice sites or the change in individual layer thicknesses are immaterial in the x-ray structure analysis, such that they are averaged out overall.

In at least one aspect, the phosphor has the general empirical formula KₓAl_{11+y}O_{17+z}:Mn²⁺ or KₓAl_{11+y}O_{17+z}:(Mn²⁺,Eu²⁺) with 0<x<2, where
when 0<x<1: y=⅓ (1−x) and z=0 or y=0 and z=−½ (1−x);
when x=1: y=0 and z=0 and
when 1<x<2: y=0 and z=½ (x−1) or y=−⅓ (x−1) and z=0.

Phosphors in this aspect show emission in the green spectral region with a peak wavelength between 490 nm and 530 nm.

“Peak wavelength” in the present context refers to the wavelength in the emission spectrum at which the maximum intensity in the emission spectrum lies.

In at least one aspect, the peak wavelength of the phosphor is in the green region of the electromagnetic spectrum, optionally, between 490 nm and 530 nm.

In at least one aspect, the phosphor has the general empirical formula KₓAl_{11+y}O_{17+z}:Mn²⁺ or KₓAl_{11+y}O_{17+z}:(Mn²⁺, Eu²⁺) with 1≤x<2, where
when x=1: y=0 and z=0 and
when 1<x<2: y=0 and z=½ (x−1) or y=−⅓ (x−1) and z=0.

Phosphors in this aspect show emission in the green spectral region with a peak wavelength between 490 nm and 530 nm. In addition, the full width at half maximum may be below 30 nm. The full width at half maximum is very small compared to that of known green phosphors. On account of the small full width at half maximum, it is possible to achieve a high color purity and to enhance the efficiency and light yield of a conversion LED containing this phosphor.

In at least one aspect, the phosphor has the general empirical formula KₓAl_{11+y}O_{17+z}:Mn²⁺ or KₓAl_{11+y}O_{17+z}:(Mn²⁺, Eu²⁺) with 0.5<x<1.5, where
when 0.5<x<1: y=⅓ (1−x) and z=0 or y=0 and z=−½ (1−x);
when x=1: y=0 and z=0 and
when 1<x<1.5: y=0 and z=½ (x−1) or y=−⅓ (x−1) and z=0.

In at least one aspect, the phosphor has the general empirical formula KₓAl_{11+y}O_{17+z}:Mn²⁺ or KₓAl_{11+y}O_{17+z}:(Mn²⁺, Eu²⁺) with 0.7≤x≤1.3, where
when 0.7≤x<1: y=⅓ (1−x) and z=0 or y=0 and z=−½ (1−x);
when x=1: y=0 and z=0 and
when 1<x≤1.3: y=0 and z=½ (x−1) or y=−⅓ (x−1) and z=0.

In at least one aspect, the phosphor has the general empirical formula KₓAl_{11+y}O_{17+z}:Mn²⁺ or KₓAl_{11+y}O_{17+z}:(Mn²⁺, Eu²⁺) with 0.8≤x≤1.2, where
when 0.8≤x<1: y=⅓ (1−x) and z=0;
when x=1: y=0 and z=0 and
when 1<x≤1.2: y=0 and z=½ (x−1).

Mn²⁺ or Mn²⁺ and Eu²⁺ may, in one aspect, be present in molar percentages between 0.1 mol % to 20 mol %, 1 mol % to 10 mol %, 0.5 mol % to 5 mol %, 2 mol % to 5 mol %. Here and hereinafter, molar percentages for Mn²⁺ or Mn²⁺ and Eu²⁺ are understood as molar percentages based on the molar proportions of potassium in the respective phosphor.

Efficient potassium aluminate phosphors are unknown to date to the inventors. In some aspects of this disclosure, the Mn²⁺- or Mn²⁺- and Eu²⁺-doped potassium aluminate phosphors have been found to be particularly efficient. These phosphors, when excited with primary radiation in the range between 330 nm and 470 nm, emit secondary radiation in the green region of the electromagnetic spectrum, for example, with a peak wavelength between 490 nm and 530 nm and a full width at half maximum below 30 nm. By virtue of the small full width at half maximum, the phosphors show minor emission in the UV region, if any, and are thus particularly efficient since the emission lies solely or predominantly in the visible region of the electromagnetic spectrum. The position of the peak wavelength on the one hand and the small full width at half maximum means that the phosphors of the disclosure are attractive for many lighting applications. For example, it is possible to provide white-emitting lighting devices having a high CRI (color rendering index).

The inventors have thus recognized that it is possible to provide a phosphor having properties that have not been possible to provide to date.

In at least one aspect, the Mn²⁺-doped potassium aluminate phosphor is obtainable from the reactants K₂CO₃, Al₂O₃ and MnCO₃, and the Eu²⁺- and Mn²⁺-doped potassium aluminate phosphor from the reactants K₂CO₃, Al₂O₃, MnCO₃ and Eu₂O₃.

The provided aspects of the phosphor may be produced by processes provided hereinafter. All the features described for the phosphor may also be applicable to the process for preparation thereof, and vice versa.

A process is provided for preparation of an Mn²⁺- or Eu²⁺- and Mn²⁺-doped potassium aluminate phosphor.

The process includes the following process steps:

A) blending reactants of the phosphor,

B) heating the blend obtained in A) to a temperature T1 between 1000° C. and 1700° C., for example, 1500° C.,

C) calcining the blend at a temperature T1 between 1000° C. and 1700° C., for example, 1500° C., for 1 hour to 20 hours, for example, for 4 hours to 8 hours.

In at least one aspect, the reactants used in process step A) are K₂CO₃, Al₂O₃ and MnCO₃ for preparation of the Mn²⁺-doped potassium aluminate phosphor, or K₂CO₃, Al₂O₃, MnCO₃ and Eu₂O₃ for preparation of the Eu²⁺ and Mn²⁺-doped potassium aluminate phosphor. The reactants may, for example, be present and used in powder form.

In one aspect, process step C) is followed by a further process step:

D) cooling the blend to room temperature. Room temperature is, for example, understood to mean 20° C.

In one aspect, process steps D), C) and B) are performed under an N₂ atmosphere or a forming gas atmosphere. A forming gas atmosphere is, for example, understood to mean an N₂ atmosphere with up to 7.5% H₂.

The process for preparation is very easy to perform compared to many other preparation processes for phosphors. The reactants are commercially available inexpensively, which means that the phosphor is also of economic interest.

The disclosure further relates to a lighting device. The lighting device includes the Mn²⁺- or the Eu²⁺- and Mn²⁺-doped potassium aluminate phosphor. All details and definitions of the Mn²⁺- or the Eu²⁺- and Mn²⁺-doped potassium aluminate phosphor are also applicable to the lighting device and vice versa.

In at least one aspect, the lighting device has a semiconductor layer sequence. The semiconductor layer sequence is set up for emission of electromagnetic primary radiation.

In at least one aspect, the semiconductor layer sequence includes at least one III-V compound semiconductor material. The semiconductor material is, for example, a nitride compound semiconductor material, such as AlₙIn₁₋ₙ₋ₘGaₘN, where, in each case, 0≤n≤1, 0≤m≤1 and n+m≤1. It is possible here for the semiconductor layer sequence to include dopants and additional constituents. For the sake of simplicity, however, constituents of the semiconductor layer sequence, i.e. Al, Ga, In and N, are shown, even though they may be partly replaced and/or supplemented by small amounts of further substances. For example, the semiconductor layer sequence may be formed from InGaN.

The semiconductor layer sequence includes an active layer having at least one pn junction and/or having one or more quantum well structures. In the operation of the lighting device, electromagnetic primary radiation is generated in the active layer. A wavelength or the emission maximum of the primary radiation may optionally be in the ultraviolet and/or visible region, for example, at wavelengths between 330 nm and 470 nm inclusive, for example between 400 nm and 460 nm inclusive.

In at least one aspect, a wavelength or the emission maximum of the primary radiation in the case of use of Mn²⁺-doped potassium aluminate phosphor is about 460 nm. The Mn²⁺-doped potassium aluminate phosphor can be efficiently excited at about 460 nm.

In at least one aspect, a wavelength or the emission maximum of the primary radiation in the case of use of the Eu²⁺- and Mn²⁺-doped potassium aluminate phosphor is between 330 nm and 470 nm inclusive, for example 460 nm.

In at least one aspect, the lighting device is a light-emitting diode, LED for short, for example, a conversion LED. In that case, the lighting device is optionally set up to emit white or colored light.

In combination with the Mn²⁺- or Eu²⁺- and Mn²⁺-doped potassium aluminate phosphor present in the lighting device, the lighting device is optionally set up to emit green light or white light in partial conversion or in full conversion.

The lighting device includes a conversion element. For example, the conversion element includes the Mn²⁺- or the Eu²⁺- and Mn²⁺-doped potassium aluminate phosphor. The phosphor at least partly or fully converts the electromagnetic primary radiation to electromagnetic secondary radiation in the green region of the electromagnetic spectrum.

In at least one aspect, the conversion element or the lighting device, aside from the Mn²⁺- or the Eu²⁺- and Mn²⁺-doped potassium aluminate phosphor, does not include any further phosphor. The conversion element may also include the phosphor. Optionally, the Mn²⁺- or the Eu²⁺- and Mn²⁺-doped potassium aluminate phosphor is set up to partly convert the primary radiation. The overall radiation from the lighting device is thus mixed radiation composed of the primary radiation and the secondary radiation. For example, a wavelength or the emission maximum of the primary radiation is in the visible blue region, for example, at wavelengths between 400 nm and 470 nm inclusive. It is therefore possible with the lighting device in this aspect to achieve many color loci in the blue to green region of the electromagnetic spectrum. It is thus possible to fix the color locus according to customer-specific wishes (“color on demand”).

The lighting devices are suitable, for example, for signaling lights such as blue lights for police vehicles, ambulances, emergency doctors' vehicles or fire department vehicles.

The lighting device that emits white mixed radiation is suitable for general lighting, for example for office spaces. The Mn²⁺- or the Eu²⁺- and Mn²⁺-doped potassium aluminate phosphor described here has a large overlap with the melanopic curve. Radiation emitted by the Mn²⁺- or Eu²⁺- and Mn²⁺-doped potassium aluminate phosphor of the disclosure or by the white-emitting lighting device can thus reduce tiredness and promote the ability to concentrate.

In at least one aspect, the conversion element, as well as the phosphor, includes a second and/or third phosphor. For example, the phosphors are embedded in a matrix material. Alternatively, the phosphors may also be present in a converter ceramic.

The lighting device may include a second phosphor for emission of radiation from the red spectral region. In other words, the lighting device in that case includes at least two phosphors: the green-emitting Mn²⁺- or Mn²⁺- and Eu²⁺-doped potassium aluminate phosphor and a red-emitting phosphor. The lighting device is, for example, set up for a partial conversion, the primary radiation optionally being selected from the blue spectral region and optionally being partly converted. The resulting overall radiation from the lighting device is then, for example, white mixed radiation.

The lighting device may include a third phosphor for emission of radiation from the blue spectral region. In other words, the lighting device in that case includes at least three phosphors: the green-emitting Mn²⁺- or Mn²⁺- and Eu²⁺-doped potassium aluminate phosphor, a red-emitting phosphor and a blue-emitting phosphor. The lighting device is, for example, set up for full conversion, with the primary radiation optionally being selected from the UV to blue spectral region and optionally being fully converted. The resulting overall radiation from the lighting device is then, for example, white mixed radiation. Variations in the white overall radiation, such as a change in the color locus and in color rendering, caused by the primary radiation can largely be avoided since the blue component of the overall radiation corresponds to the secondary radiation from the third phosphor and the primary radiation makes barely any contribution to the overall radiation, if any.

The red spectral region may be considered to be the region of the electromagnetic spectrum between 580 nm and 780 nm.

The UV to blue spectral region may be considered to be the region of the electromagnetic spectrum between 330 nm and 490 nm, where the blue spectral region is understood to mean the range between 400 nm and 490 nm inclusive, and the UV spectral region to be the range between 350 nm and 400 nm inclusive.

### WORKING EXAMPLES

AB1: KAl₁₁O₁₇:Mn²⁺

AB2: KₓAl_{11+y}O_{17+z}:(Mn²⁺, Eu²⁺) with x=1.2; z=0 and y=−⅓ (x−1).

Working examples AB1 and AB2 of the phosphor of the disclosure were produced as follows: K₂CO₃, MnCO₃ and Al₂O₃ (AB1) or K₂CO₃, MnCO₃, Al₂O₃ and Eu₂O₃ (AB2) were mixed, and the mixture was heated in a corundum crucible to a temperature of 1000° C. to 1700° C. under N₂ or N₂ with up to 7.5% H₂ and kept at that temperature for 1 h to 20 h. After cooling, single crystals of the phosphor are obtained. It was possible here to observe the partial formation of Al₂O₃ as secondary phase.

The comparative example (VB1) was prepared analogously, but without addition of MnCO₃.

VB1: KₓAl_{11+y}O_{17+z}:Eu²⁺ with x=0.8; y=0 and z=−½ (1−x).

The starting weights of the reactants can be found in table 1 below.

TABLE 1

| | | Molar amount/ | |
|---|---|---|---|
| | Reactant | mmol | Mass/g |
| VB1 | K₂CO₃ | 7.026 | 0.971 |
| | Al₂O₃ | 85.86 | 8.754 |
| | Eu₂O₃ | 0.781 | 0.275 |
| AB1 | K₂CO₃ | 7.858 | 1.086 |
| | Al₂O₃ | 85.65 | 8.733 |
| | MnCO₃ | 1.575 | 0.181 |
| AB2 | K₂CO₃ | 6.953 | 0.961 |
| | Al₂O₃ | 84.24 | 8.589 |
| | MnCO₃ | 1.549 | 0.178 |
| | Eu₂O₃ | 0.773 | 0.272 |

Table 2 shows crystallographic data of AB2.

TABLE 2

| | AB2 |
|---|---|
| Structure type | sodium β-aluminate |
| Crystal system | hexagonal |
| Space group | P6₃/mmc (194) |
| Lattice parameters | |
| a/pm | 560.47(2) |
| b/pm | 560.47(2) |
| c/pm | 2270.59(11) |
| α | 90 |
| β | 90 |
| γ | 120 |
| Volume/nm³ | 0.61769(5) |
| Density ρ/g cm⁻³ | 3.3 |
| T/K | 296(2) |
| Total reflections | 3775 |
| Independent | 277 |
| reflections | |
| Reciprocal space | −6 ≤ h ≤ 6 |
| measured | −6 ≤ k ≤ 6 |
| | −28 ≤ l ≤ 27 |
| Rₐₗₗ, wR_{ref} | 7.35%, 18.64% |
| GooF | 1.143 |

Table 3 shows atomic positions in the structure of a single crystal of sample AB2, and table 4 shows the occupation and isotropic shift parameters in the structure of AB2.

TABLE 3

| | Wyckoff | | | |
|---|---|---|---|---|
| Atom | position | x | y | z |
| K1 | 2d | ⅔ | ⅓ | ¼ |
| K2 | 12j | 0.199(8) | 0.099(4) | 0.25 |
| Al1 | 2a | 0 | 0 | 0.5 |
| Al2 | 12k | 0.3352(4) | 0.16759(19) | 0.39404(8) |
| Al3 | 4f | ⅓ | ⅔ | 0.12482(13) |
| Al4 | 4f | ⅓ | ⅔ | 0.32500(14) |
| O1 | 4f | ⅓ | ⅔ | 0.9443(3) |
| O2 | 12k | 0.3141(9) | 0.1570(5) | 0.5498(2) |
| O3 | 4e | 0 | 0 | 0.3584(3) |
| O4 | 12k | 0.5025(5) | 0.4975(5) | 0.35493(17) |
| O5 | 2c | ⅓ | ⅔ | ¼ |

Mn²⁺ and Eu²⁺ here occupy the positions of potassium (K1 and/or K2), but are not listed separately in tables 3 and 4.

TABLE 4

| Atom | Occupation | U |
|---|---|---|
| K1 | 1 | Uₐₙᵢₛ* |
| K2 | 0.053(9) | 0.008(12) |
| Al1 | 1 | 0.0105(11) |
| Al2 | 1 | 0.0071(8) |
| Al3 | 1 | 0.0036(9) |
| Al4 | 1 | 0.0070(9) |
| O1 | 1 | 0.0054(18) |
| O2 | 1 | 0.0079(12) |
| O3 | 1 | 0.0095(17) |
| O4 | 1 | 0.0083(12) |
| O5 | 1 | 0.019(3) |

*K1 was anisotropically refined U₁₁ = 0.042(2), U₂₂ = 0.042(2), U₃₃ = 0.012(2), U₁₂ = 0.0208(10).

### BRIEF DESCRIPTION OF THE DRAWINGS

In the following, the phosphor and the lighting device described herein are explained in more detail in conjunction with non-limiting aspects and the associated figures.

FIG. 1 shows a detail of the crystal structure of the phosphor of the disclosure.

FIGS. 2, 3, 4A, 5 show emission spectra.

FIG. 4B shows a comparison of optical data of phosphors.

FIGS. 6, 7 and 8 show conversion LEDs.

The figures and the proportions of the elements depicted in the figures relative to each other are not to be considered as true to scale. Rather, individual elements may be displayed in an exaggeratedly large format for better presentation and/or comprehensibility.

### DETAILED DESCRIPTION

FIG. 1 shows a detail of the crystal structure of the phosphor KₓAl_{11+y}O_{17+z}:(Mn²⁺, Eu²⁺) or KₓAl_{11+y}O_{17+z}:Mn²⁺ along the crystallographic b axis. The hatched triangles are AlO₄ tetrahedra and AlO₆ octahedra in which Al is at the centers and oxygen is at the vertices of the tetrahedra or octahedra. The AlO₄ tetrahedra and AlO₆ octahedra form spinel-like layers. Between the layers are arranged K⁺ ions with the Wyckoff position 2d or the Wyckoff position 2d and 12j (table 3) and O²⁻ ions (not shown). Mn²⁺ or Mn²⁺ and Eu²⁺ here may partly replace K⁺ or Al³⁺.

If the proportion x of potassium is 0<x<1, the Wyckoff position 2d is not fully occupied by potassium ions and the Wyckoff position 12j is unoccupied.

If the proportion x of potassium is x=1, the Wyckoff position 2d is fully occupied by potassium ions and the Wyckoff position 12j is unoccupied.

If the proportion x of potassium is 1<x<2, the Wyckoff position 2d is fully occupied by potassium ions and the Wyckoff position 12j is partly occupied by potassium ions.

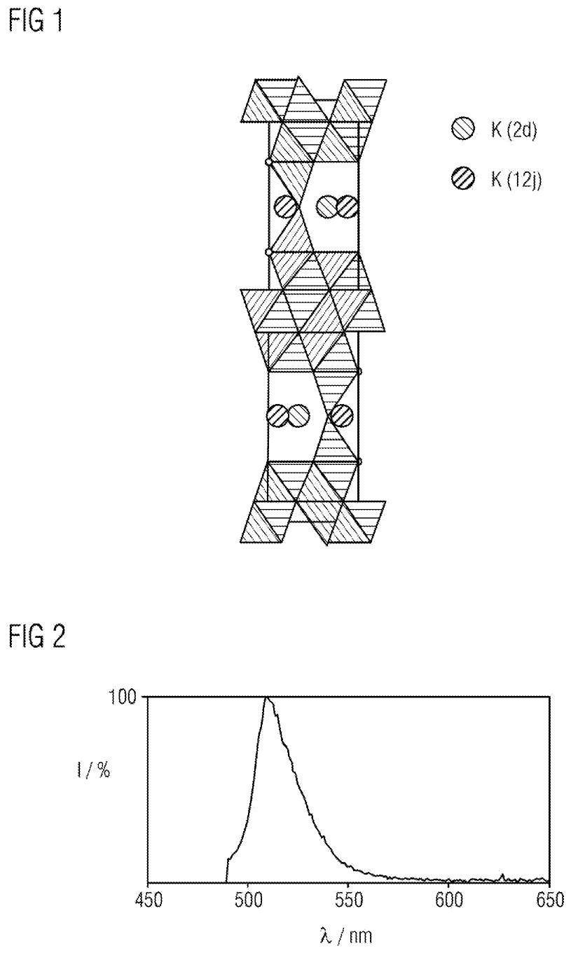

FIG. 2 shows the emission spectrum of KAl₁₁O₁₇:Mn²⁺ (AB1). Plotted on the x axis is the wavelength in nm, and on the y axis the intensity in percent. To measure the emission spectrum, the phosphor was excited with primary radiation having a peak wavelength of 460 nm. The phosphor has a peak wavelength of about 509 nm and a full width at half maximum of 24 nm.

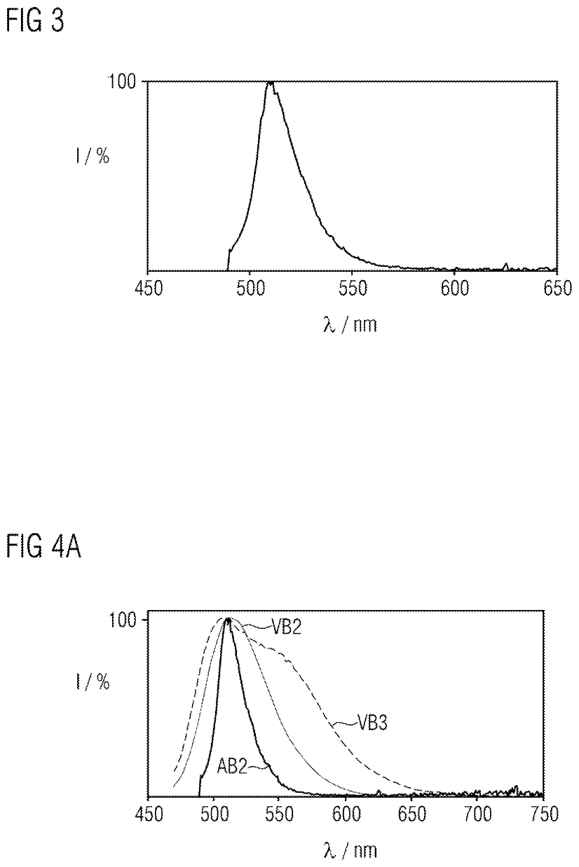

FIG. 3 shows the emission spectrum of KₓAl_{11+y}O_{17+z}:(Mn²⁺,Eu²⁺) with x=1.2; z=0 and y=−⅓ (x−1) (AB2). Plotted on the x axis is the wavelength in nm, and on the y axis the intensity in percent. To measure the emission spectrum, the phosphor was excited with primary radiation having a peak wavelength of 460 nm. The phosphor has a peak wavelength of about 511 nm and a full width at half maximum of 23 nm.

Table 5 below shows a comparison of emission properties of AB1, AB2 and VB1.

TABLE 5

| | λₚᵣᵢₘ | λₚₑₐₖ | FWHM | LER |
|---|---|---|---|---|
| | (nm) | (nm) | (nm) | (lmW⁻¹) |
| VB1 | 400 | 450 | 51 | 0.137 |
| VB1 | 460 | *— | — | — |
| AB1 | 400 | **— | — | — |
| AB1 | 460 | 509 | 24 | 0.533 |
| AB2 | 400 | 511 | 23 | 0.509 |
| AB2 | 460 | 511 | 23 | 0.542 |

*Not measurable owing to overlap with primary radiation (λₚᵣᵢₘ).
**Excitation not possible with primary radiation (λₚᵣᵢₘ) of 400 nm.

As apparent from table 5, the peak wavelengths of working examples AB1 and AB2 are in the green region of the electromagnetic spectrum with full widths at half maximum below 30 nm, while the peak wavelength of the solely Eu²⁺-doped potassium aluminate phosphor (VB1) is in the blue region of the electromagnetic spectrum with a full width at half maximum of 51 nm. In some aspects, doping of the potassium aluminate with Mn²⁺ or co-doping of the already Eu²⁺-doped potassium aluminate with Mn²⁺ results in a shift in the peak wavelength into the green region of the electromagnetic spectrum and a distinct reduction in the half height width of the emission band. It is thus possible with AB1 and AB2 to achieve a distinctly higher light yield (LER) than with VB1.

The phosphor of the disclosure may be present as the sole phosphor in a lighting device or conversion LED which, in full conversion, emits overall radiation in the green region of the electromagnetic spectrum or, in partial conversion, emits overall radiation in the blue to green region of the electromagnetic spectrum. The lighting device or conversion LED that emits overall radiation in the blue to green region of the electromagnetic spectrum, in partial conversion, is suitable, for example, for signal lights such as blue lights, for example, police vehicles, ambulances, emergency doctors' vehicles or fire department vehicles.

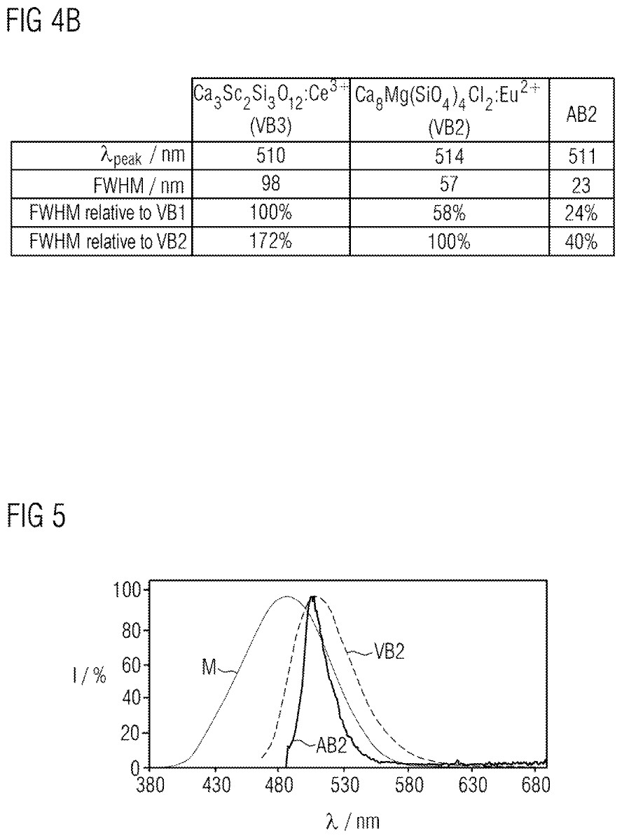

FIG. 4A shows emission spectra of the phosphor AB2 and two comparative examples Ca₈Mg(SiO₄)₄Cl₂: Eu²⁺ (VB2) and Ca₃Sc₂Si₃O₁₂:Ce³⁺ (VB3).

FIG. 4B shows a comparison of optical data of the phosphor AB2 and two comparative examples Ca₈Mg(SiO₄)₄Cl₂:Eu²⁺ (VB2) and Ca₃Sc₂Si₃O₁₂:Ce³⁺ (VB3). The phosphors show a similar peak wavelength. AB2, compared to VB2 and VB3, shows a distinctly smaller full width at half maximum. By virtue of the small full width at half maximum, the phosphor of the disclosure has distinctly smaller radiation losses caused by partial emission in the UV region than conventional phosphors with peak wavelengths in the green region of the electromagnetic spectrum.

FIG. 5 shows emission spectrum of the phosphor AB2 and of a comparative example Ca₈Mg(SiO₄)₄Cl₂:Eu²⁺ (VB2). In addition, FIG. 5 shows the melanopic sensitivity curve M. The melanopic sensitivity curve M shows the wavelengths with which melatonin production in the body can be best suppressed. As apparent, the emission spectrum of AB2 has a much greater overlap with the melanopic sensitivity curve M than the emission spectrum of VB2. It is consequently possible with the phosphor of the disclosure to generate melanopically effective light, such that this light can be used effectively for suppression of melatonin formation. If a person is exposed to the radiation from a lighting device containing the phosphor AB2, this can lead to increased attentiveness or else the ability of the person to concentrate. Lighting devices including the phosphor of the disclosure can thus be used for room lighting, for example, for “human centric lighting” applications.

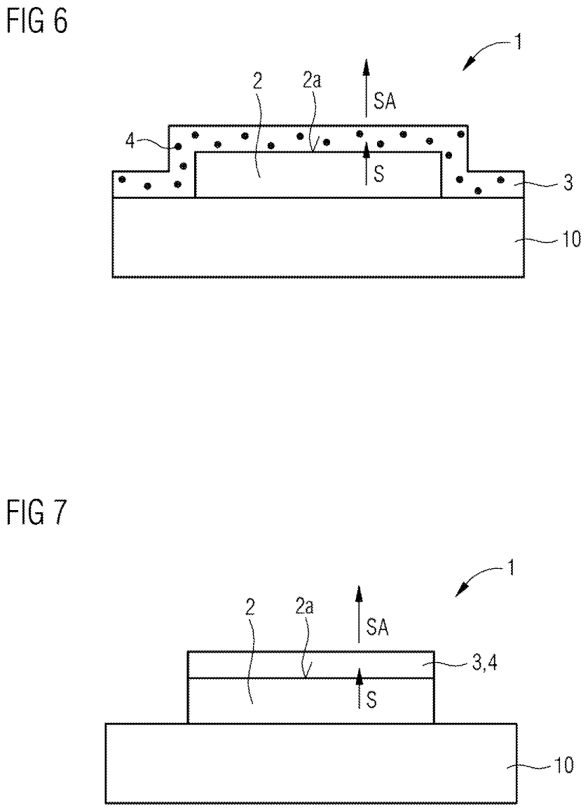

FIGS. 6 to 8 each show schematic side views of various aspects of lighting devices described here, for example, conversion LEDs.

The conversion LEDs of FIGS. 6 to 8 include at least one Mn²⁺ or Eu²⁺ and Mn²⁺-doped potassium aluminate phosphor described here. In addition, a further phosphor or a combination of phosphors may be present in the conversion LED. The additional phosphors are known to the person skilled in the art and are therefore not mentioned explicitly at this point.

The conversion LED according to FIG. 6 has a semiconductor layer sequence 2 disposed on a substrate 10. The substrate 10 may, for example, be in reflective form. Disposed atop the semiconductor layer sequence 2 is a conversion element 3 in the form of a layer. The semiconductor layer sequence 2 has an active layer (not shown) that emits with a wavelength between 330 nm and 470 nm inclusive in the operation of the conversion LED. The conversion element 3 is disposed in the beam path of the primary radiation S. The conversion 3 includes a matrix material, for example a silicone, epoxy resin or hybrid material, and particles of the phosphor 4.

For example, the phosphor 4 has an average grain size of 10 μm. The phosphor 4 is capable of converting the primary radiation S, in the operation of the conversion LED, at least partly or fully to a secondary radiation SA in the green spectral region. The phosphor 4 is distributed homogeneously in the matrix material in the conversion element 3 within the scope of manufacturing tolerance.

Alternatively, the phosphor 4 may also be distributed in the matrix material with a concentration gradient.

Alternatively, the matrix material may also be absent, such that the phosphor 4 takes the form of a ceramic converter.

The conversion element 3 is applied over the full area of the radiation exit surface 2a of the semiconductor layer sequence 2 and over the lateral surfaces of the semiconductor layer sequence 2, and is in direct mechanical contact with the radiation exit surface 2a of the semiconductor layer sequence 2 and the lateral surfaces of the semiconductor layer sequence 2. The primary radiation S can also exit via the lateral surfaces of the semiconductor layer sequence 2.

The conversion element 3 may be applied, for example, by injection molding, compression-injection molding or spray-coating methods. Moreover, the conversion LED has electrical contacts (not shown here), the formation and arrangement of which is known to the person skilled in the art.

Alternatively, the conversion element may also be prefabricated and be applied to the semiconductor layer sequence 2 by means of what is called a pick-and-place process.

FIG. 7 shows a further working example of a conversion LED 1. The conversion LED 1 has a semiconductor layer sequence 2 on a substrate 10. The conversion element 3 is formed on the semiconductor layer sequence 2. The conversion element 3 takes the form of a platelet. The platelet may include particles of the phosphor 4 that have been sintered together and hence be a ceramic platelet, or the platelet includes, for example, glass, silicone, an epoxy resin, a polysilazane, a polymethacrylate or a polycarbonate as matrix material with particles of the phosphor 4 embedded therein.

The conversion element 3 has been applied over the full area of the radiation exit surface 2a of the semiconductor layer sequence 2. For example, no primary radiation S exits via the lateral surfaces of the semiconductor layer sequence 2; instead, it does so predominantly via the radiation exit surface 2a. The conversion element 3 may have been applied by means of a bonding layer (not shown), for example of silicone, atop the semiconductor layer sequence 2.

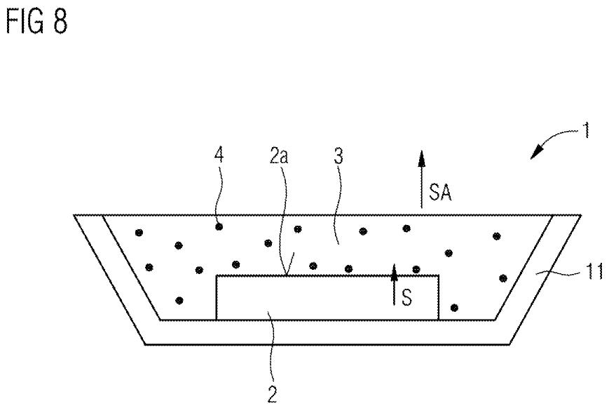

The conversion LED 1 according to FIG. 8 has a housing 11 with a recess. Disposed in the recess is a semiconductor layer sequence 2 having an active layer (not shown). In the operation of the conversion LED, the active layer emits primary radiation S with a wavelength of between 330 nm and 470 nm inclusive.

The conversion element 3 takes the form of an encapsulation of the layer sequence in the recess, and includes a matrix material, for example a silicone, and a phosphor 4, for example KAl₁₁O₁₇:(Mn²⁺,Eu²⁺). In the operation of the conversion LED 1, the phosphor 4 converts the primary radiation S at least partly to a secondary radiation SA. Alternatively, the phosphor converts the primary radiation S fully to secondary radiation SA.

It is also possible that the phosphor 4 is arranged spaced apart from the semiconductor layer sequence 2 or the radiation exit surface 2a in the working examples of FIGS. 6 to 8. This can be achieved, for example, by sedimentation or by application of the conversion layer atop the housing.

For example, by contrast with the aspect of FIG. 8, the encapsulation may include a matrix material, for example silicone, with the conversion element 3 applied as a layer atop the housing 11 and atop the encapsulation, spaced apart on the encapsulation from the semiconductor layer sequence 2.

The working examples described in conjunction with the figures and features thereof may also be combined with one another in further working examples, even if such combinations are not shown explicitly in the figures. In addition, the working examples described in conjunction with the figures may have additional or alternative features according to the description in the general part.

### LIST OF REFERENCE NUMERALS

1 lighting device or conversion LED
2 semiconductor layer sequence or semiconductor chip
2a radiation exit surface
   3 conversion element
4 phosphor
10 substrate
11 housing
S primary radiation
SA secondary radiation
LED light-emitting diode
LER light yield
λₚₑₐₖ peak wavelength
ppm parts per million
AB working example
VB comparative example
g grams
I intensity
mol % mole percent
nm nanometers
° C. degrees Celsius
lm lumens
W watts
mmol millimoles

1.-14. (canceled)

15. A conversion light emitting diode (LED) comprising:
a semiconductor layer sequence configured to emit electromagnetic primary radiation; and
a conversion element comprising an Mn²⁺-doped potassium aluminate phosphor or an Eu²⁺- and Mn²⁺-doped potassium aluminate phosphor, wherein the conversion element at least partly converts the electromagnetic primary radiation to electromagnetic secondary radiation, wherein the Mn²⁺-doped potassium aluminate phosphor or the Eu²⁺- and Mn²⁺-doped potassium aluminate phosphor has a general empirical formula
KₓAl_{11+y}O_{17+z}:Mn²⁺, or
KₓAl_{11+y}O_{17+z}:(Mn²⁺,Eu²⁺),
where x+3(11+y)=2(17+z), 0<x<2, −½<z<½, and −⅓<y<⅓.

16. The conversion LED of claim 15, wherein the Mn²⁺-doped potassium aluminate phosphor or the Eu²⁺- and Mn²⁺-doped potassium aluminate phosphor has the general empirical formula KₓAl_{11+y}O_{17+z}:Mn²⁺ or KₓAl_{11+y}O_{17+z}:(Mn²⁺,Eu²⁺) with 0<x<2, where
when 0<x<1, then y=⅓ (1−x) and z=0 or y=0 and z=−½ (1−x);
when x=1, then y=0 and z=0; and
when 1<x<2, then y=0 and z=½ (x−1) or y=−⅓ (x−1) and z=0.

17. The conversion LED of claim 15, wherein the Mn²⁺-doped potassium aluminate phosphor or the Eu²⁺- and Mn²⁺-doped potassium aluminate phosphor has the general empirical formula KₓAl_{11+y}O_{17+z}:Mn²⁺ or KₓAl_{11+y}O_{17+z}:(Mn²⁺,Eu²⁺) with 0.5<x<1.5, wherein
when 0.5<x<1, then y=⅓ (1−x) and z=0 or y=0 and z=−½ (1−x);
when x=1, then y=0 and z=0; and
when 1<x<1.5, then y=0 and z=½ (x−1) or y=−⅓ (x−1) and z=0.

18. The conversion LED of claim 15, wherein the Mn²⁺-doped potassium aluminate phosphor or the Eu²⁺- and Mn²⁺-doped potassium aluminate phosphor has the general empirical formula KₓAl_{11+y}O_{17+z}:Mn²⁺ or KₓAl_{11+y}O_{17+z}:(Mn²⁺,Eu²⁺) with 0.7≤x≤1.3, wherein
when 0.7≤x<1, then y=⅓ (1−x) and z=0 or y=0 and z=−½ (1−x);
when x=1, then y=0 and z=0; and
when 1<x≤1.3, then y=0 and z=½ (x−1) or y=−⅓ (x−1) and z=0.

19. The conversion LED of claim 18, wherein 0.8≤x≤1.2 and
when 0.8≤x<1, then y=⅓ (1−x) and z=0;
when x=1, then y=0 and z=0; and
when 1<x≤1.2, then y=0 and z=½ (x−1).

20. The conversion LED of claim 18, wherein 0.8≤x≤1.2 and
when 0.8≤x<1, then y=0 and z=−½ (1−x);
when x=1, then y=0 and z=0 and
when 1<x≤1.2, then y=−⅓ (x−1).

21. The conversion LED of claim 15, wherein the Mn²⁺-doped potassium aluminate phosphor or the Eu²⁺- and Mn²⁺-doped potassium aluminate phosphor crystallizes in the hexagonal P6₃/mmc space group.

22. The conversion LED of claim 15, wherein the Eu²⁺- and Mn²⁺-doped potassium aluminate phosphor has the general empirical formula KₓAl_{11+y}O_{17+z}:(Mn²⁺,Eu²⁺).

23. The conversion LED of claim 15, wherein the Mn²⁺-doped potassium aluminate phosphor is a product of reactants K₂CO₃, Al₂O₃, and MnCO₃.

24. The conversion LED of claim 15, wherein the Eu²⁺- and Mn²⁺-doped potassium aluminate phosphor is a product of reactants K₂CO₃, Al₂O₃, MnCO₃, and Eu₂O₃.
